(19) United States
(12) Patent Application Publication
(10) Pub. No.: US 2013/0180583 A1
(43) Pub. Date: Jul. 18, 2013

(54) CONDUCTIVE PASTE FOR FINE-LINE HIGH-ASPECT-RATIO SCREEN PRINTING IN THE MANUFACTURE OF SEMICONDUCTOR DEVICES

(71) Applicant: E I DU PONT DE NEMOURS AND COMPANY, Wilmington, DE (US)

(72) Inventors: WILLIAM J. BORLAND, Chapel Hill, NC (US); John D. Summers, Chapel Hill, NC (US)

(73) Assignee: E I DU PONT DE NEMOURS AND COMPANY, Wilmington, DE (US)

(21) Appl. No.: 13/740,449

(22) Filed: Jan. 14, 2013

Related U.S. Application Data
(60) Provisional application No. 61/587,159, filed on Jan. 17, 2012.

(51) Int. Cl. H01L 31/0224

(52) U.S. Cl. CPC H01L 31/022425
USPC 136/256; 252/500; 252/514

(57) ABSTRACT

This invention relates to thick film conductive paste comprised of one or more electrically conductive powders, one or more glass fits, and an organic medium comprising solvent and cellulose ester resin. This paste enables fine line printing in the manufacture of soar cells and exhibits reduced line spreading during the drying and firing steps. Paste stability is also improved. Also provided is a semiconductor device comprising an electrode formed from the thick film conductive paste.

### FIELD OF THE INVENTION

This invention relates to thick film conductive paste useful in forming fine-line high-aspect-ratio electrodes on semiconductor devices, particularly silicon solar cells, and to semiconductor devices comprising an electrode formed from the thick film conductive paste.

### TECHNICAL BACKGROUND OF THE INVENTION

A conventional solar cell structure with a p-type base has a negative electrode that is typically on the front-side or sun side of the cell and a positive electrode on the back side. Radiation of an appropriate wavelength falling on a p-n junction of a semiconductor body serves as a source of external energy to generate electron-hole pairs in that body. Because of the potential difference which exists at a p-n junction, holes and electrons move across the junction in opposite directions and thereby give rise to a flow of electric current that is capable of delivering power to an external circuit. Most solar cells are in the form of a silicon wafer that has been metallized, i.e., provided with metal electrodes that are electrically conductive. Typically thick film pastes or inks (referred to simply as “pastes” hereafter) are screen-printed onto the substrate and fired to form the electrodes.

The front or sun side of the silicon wafer is often coated with an anti-reflective coating (ARC) to prevent reflective loss of incoming sunlight, thus increasing the efficiency of the solar cell. Typically, a two-dimensional electrode grid pattern (“front electrode”) makes a connection to the n-side of the silicon, and a coating of aluminum on the opposite side (“back electrode”) makes connection to the p-side of the silicon. These contacts are the electrical outlets from the p-n junction to the outside load.

Typically, the paste that is screen-printed to form the front electrodes of silicon solar cells contains electrically conductive particles, glass frit and an organic medium. After screen-printing, the wafer and paste are fired in air, typically at furnace setpoint temperatures of about 650-1000° C. for a few seconds to form a dense solid of electrically conductive traces. The organic components are burned away in this firing step. Also during this firing step, the glass frit and any added flux reacts with and etches through the anti-reflective coating and facilitates the formation of intimate silicon-electrode contact. The glass frit and any added flux also provide adhesion to the substrate and aid in the adhesion of subsequently soldered leads to the electrode. Good adhesion to the substrate and high solder adhesion of the leads to the electrode are important to the performance of the solar cell as well as the manufacturability and reliability of the solar modules. Fine-line electrodes with high aspect ratios are desirable to provide minimal shadowing of the front surface of the solar cell and reduced resistance. Stability of the paste is an additional requirement.

Although various pastes for forming solar cell electrodes exist, there is a need for paste which provides improved performance and for solar cells with electrodes formed from such paste.

### SUMMARY OF THE INVENTION

The present invention provides a thick film conductive paste comprising:
a) one or more electrically conductive powders;
b) one or more glass frits; and
c) an organic medium comprising solvent and cellulose ester resin, wherein the one or more electrically conductive powders and the one or more glass frits are dispersed in the organic medium.

In an embodiment the cellulose ester resin is selected from the group consisting of cellulose acetate propionate, cellulose acetate butyrate, and mixtures thereof.

The present invention also provides a semiconductor device, and in particular a solar cell, comprising an electrode formed from the thick film conductive paste of the invention, wherein the thick film conductive paste has been fired to remove the organic medium and form the electrode.

### BRIEF DESCRIPTION OF THE FIGURES

FIGS. 1A-1F illustrate the fabrication of a semiconductor device. Reference numerals shown in FIGS. 1A-1F are explained below.

10: p-type silicon substrate
20: n-type diffusion layer
30: ARC (e.g., silicon nitride film, titanium oxide film, or silicon oxide film)
40: p+ layer (back surface field, BSF)
60: aluminum paste deposited on back side
61: aluminum back side electrode (obtained by firing back side aluminum paste)
70: silver/aluminum paste deposited on back side
71: silver/aluminum back side electrode (obtained by firing back side silver/aluminum paste)
500: paste of the instant invention deposited on front side
501: front electrode (formed by firing front side paste 500)

### DETAILED DESCRIPTION OF THE INVENTION

The present invention addresses the need for thick film paste that will provide semiconductor devices with improved performance,

An embodiment of the present invention relates to thick film conductive paste. In one such embodiment, the thick film conductive paste is comprised of one or more electrically conductive powders, one or more glass frits, and an organic medium comprising solvent and cellulose ester resin. In an embodiment, the cellulose ester resins are selected from the group consisting of cellulose acetate butyrate, cellulose acetate propionate and mixtures thereof.

The paste of the invention containing cellulose ester resins has certain desirable properties. This paste is suitable for fine line printing in the manufacture of solar cells. It exhibits reduced line spreading during the drying and firing steps. It also exhibits improved paste stability.

In one embodiment, the one or more electrically conductive powders of the paste are silver powders. In an embodiment with silver powders, the paste is comprised of a silver powder with spherically shaped particles, a tap density of about 5 to 6, a surface area of about 0.3 to 0.6 m²/gm Ag and a particle size distribution of d₁₀ of about 1.0 to 1.5 μm, d₅₀ of about 1.5 to 2.3 μm and d₉₀ of about 2.5 to 3.5 μm. The particle size distribution numbers (d₁₀, d₅₀, d₉₀) can be measured using a Microtrac® Particle Size Analyzer from Leeds and Northrup. The d₁₀, d₅₀ and d₉₀ represent the 10th percentile, the median or 50th percentile and the 90th percentile of the particle size distribution, respectively, as measured by volume. That is, the d₅₀ (d₁₀, d₉₀) is a particle size value on the distribution such that 50% (10%, 90%) of the particles have a volume of this value or less. In one such embodiment, the paste is comprised of a silver powder with spherically shaped particles, a tap density of about 5 to 6, a surface area of about 0.3 to 0.6 m²/gm Ag and a particle size distribution of d₁₀ of about 1.0 to 1.5 μm, d₅₀ of about 1.5 to 2.3 μm and d₉₀ of about 2.5 to 3.5 μm, solvent selected from the group consisting of diethylene glycol n-butyl ether acetate, diethylene glycol monobutyl ether, 2,2,4-trimethyl-1,3-pentadiol monoisobutyrate and mixtures thereof, and cellulose ester resin selected from the group consisting of cellulose acetate propionate, cellulose acetate butyrate, and mixtures thereof. In an embodiment, the paste is further comprised of an amide thixotrope dispersed in the organic medium. In this embodiment, the fired finger electrode lines are less than 100 μms wide and the fired finger electrode lines have high aspect ratios, i.e., the ratios of height to width are 0.2 or greater. Finger lines of such dimensions result in decreased shadowing of the front surface of the solar cell. In an embodiment, the compositions are compatible with high speed screen printing of 8 inches per sec (200 mm per sec) or higher.

An embodiment of the present invention relates to structures, wherein the structures include the thick film conductor paste. In an aspect, the structure also includes one or more insulating films. In an aspect, the structure does not include an insulating film. In an aspect, the structure includes a semiconductor substrate. In an aspect, the thick film conductor paste is deposited on the one or more insulating films. In an aspect, the thick film conductor composition is deposited directly on the semiconductor substrate.

The components of the thick film conductive paste are discussed below.

### Electrically Conductive Powders

Electrically conductive powders are selected from powders of silver, copper, palladium, mixtures thereof and mixtures of one or more of silver, copper and palladium with nickel and/or aluminum.

In an embodiment, the electrically conductive powders are silver powders. The silver powder particles may be in a spherical form, a flake form, a granular form, other irregular forms or mixtures thereof. When more than one silver powder is used the particles of the different powders may have the same form or different forms. The silver may be silver metal, alloys of silver or mixtures thereof.

In an embodiment, the electrically conductive powders are coated. The silver particles may be coated with various materials such as phosphorus. In an embodiment, the silver particles may be at least partially coated with a surfactant. The surfactant may be selected from, but is not limited to, stearic acid, palmitic acid, a salt of stearate, a salt of palmitate and mixtures thereof. Other surfactants may be utilized including laurie acid, palmitic acid, oleic acid, stearic acid, capric acid, myristic acid and linolic acid. The counter-ion can be, but is not limited to, hydrogen, ammonium, sodium, potassium and mixtures thereof.

In one embodiment, the paste is comprised of a silver powder with spherically shaped particles, a tap density of about 5 to 6, a surface area of about 0.3 to 0.6 m²/gm Ag and a particle size distribution of d₁₀ of about 1.0 to 1.5 μm, d₅₀ of about 1.5 to 2.3 μm and d₉₀ of about 2.5 to 3.5 μm. In related embodiment, the paste is further comprised of a silver powder with irregularly shaped particles, a tap density of about 0.8 to 1.2, a surface area of about 4.0 to 6.0 m²/gm Ag and a particle size distribution of d₁₀ of about 1.0 to 3.0 μm, d₅₀ of about 6.0 to 11.0 μm and d₉₀ of about 18.0 to 25.0 μm.

The silver powders may be any of a variety of percentages of the composition of the thick film conductive paste. In a non-limiting embodiment, the silver powder is from about 70 to about 93 wt % of the thick film conductive paste, wherein the wt % is based on the total weight of the paste. In a further embodiment, the silver powder is from about 80 to about 93 wt % of the thick film conductive paste, wherein the wt % is based on the total weight of the paste. In a still further embodiment, the silver powder is from about 87 to about 92 wt % of the thick film conductive paste, wherein the wt % is based on the total weight of the paste.

### Glass Frit

Various glass frits typically used in thick film pastes are useful in forming the instant paste. In an embodiment the paste contains 0.5-5 wt % glass frit, wherein the wt % is based on the total weight of the paste. In another embodiment the paste contains 1-2 wt % glass frit, wherein the wt % is based on the total weight of the paste,

The various glass frits may be prepared by mixing the oxides to be incorporated therein (or other materials that decompose into the desired oxides when heated) using techniques understood by one of ordinary skill in the art. Such preparation techniques may involve heating the mixture in air or an oxygen-containing atmosphere to form a melt, quenching the melt, and grinding, milling, and/or screening the quenched material to provide a powder with the desired particle size. Melting the mixture of oxides to be incorporated therein is typically conducted to a peak temperature of 800 to 1200° C. The molten mixture can be quenched, for example, on a stainless steel platen or between counter-rotating stainless steel rollers to form a platelet. The resulting platelet can be milled to form a powder. Typically, the milled powder has a d₅₀ of 0.1 to 3.0 microns. As used herein, “particle size” or “d₅₀” is intended to mean “average particle size”; “average particle size” means the 50% volume distribution size. One skilled in the art of producing glass frit may employ alternative synthesis techniques such as but not limited to water quenching, sol-gel, spray pyrolysis, or others appropriate for making powder forms of glass.

The oxide product of the above process is typically essentially an amorphous (non-crystalline) solid material, i.e., a glass. However, in some embodiments the resulting oxide may be amorphous, partially amorphous, partially crystalline, crystalline or combinations thereof. As used herein “glass frit” includes all such products.

The glass frit may be lead-containing or lead-free. Examples of typical lead-free glass frits useful in the composition include bismuth silicates, bismuth borosilicates, bismuth-tellurium oxides and mixtures thereof.

In one embodiment of lead-free glass frits the oxide constituents are in the compositional range of 55-90 wt % Bi₂O₃, 0.5-35 wt % 80₂, 0-5 wt % B₂O₃, 0-5 wt % Al₂O₃ and 0-15 wt % ZnO, based on the total weight of the glass composition. In another embodiment the oxide constituents are in the compositional range of 28-85 wt % Bi₂O₃, 0.1-18 wt % SiO₂, 1-25 wt % B₂O₃, 0-6 wt % Al₂O₃, 0-1 wt % CaO, 0-42 wt % ZnO, 0-4 wt % Na₂O, 0-3.5 wt % Li₂O, 0-3 wt % Ag₂O, 0-4.5 wt % CeO₂, 0-3.5 wt % SnO₂ and 0-15 wt % BiF₃.

The starting mixture used to make the Bi—Te—O glass frit includes 22 to 42 wt % Bi₂O₃ and 58 to 78 wt % TeO₂, based on the total weight of the starting mixture of the Bi—Te—O. In a further embodiment, in addition to the Bi₂O₃ and TeO₂, the starting mixture used to make the Bi—Te—O includes 0.1 to 7 wt % Li₂O and 0.1 to 4 wt % TiO₂, based on the total weight of the starting mixture of the Bi—Te—O. In a still further embodiment, the starting mixture includes 0.1 to 8 wt % B₂O₃, 0.1 to 3 wt % ZnO and 0.3 to 2 wt % P₂O₅, again based on the total weight of the starting mixture of the Bi—Te—O.

Examples of typical lead-containing glass frits useful in the composition include lead silicates, lead borosilicates and lead-tellurium oxides.

In one embodiment of lead-containing glass frits the oxide constituents are in the compositional range of 20-83 wt % PbO, 1-35 wt % SiO₂, 01.5-19 wt % B₂O₃, 0-35 wt % Bi₂O₃, 0-7 wt % Al₂O₃, 0-12 wt % ZnO, 0-4 wt % CuO, 0-7 wt % TiO₂, 0-5 wt % CdO and 0-30 PbF₂, based on the total weight of the glass composition.

Typically, the mixture of PbO and TeO₂ powders used to make the Pb—Te—O includes 5 to 95 mol % of lead oxide and 5 to 95 mol % of tellurium oxide, based on the combined powders. In one embodiment, the mixture of PbO and TeO₂ powders includes 25 to 85 mol % of lead oxide and 15 to 75 mol % of tellurium oxide, based on the combined powders. In another embodiment, the mixture of PbO and TeO₂ powders includes 25 to 65 mol % of lead oxide and 35 to 75 mol % of tellurium oxide, based on the combined powders.

In some embodiments, the mixture of PbO and TeO₂ powders further includes one or more other metal compounds. Suitable other metal compounds include TiO₂, LiO₂, B₂O₃, PbF₂, SiO₂, Na₂O, K₂O, Rb₂O, Cs₂O, Al₂O₃, MgO, CaO, SrO, BaO, V₂O₅, ZrO₂, MoO₃, Mn₂O₃, Ag₂O, ZnO, Ga₂O₃, GeO₂, In₂O₃, SnO₂, Sb₂O₃, Bi₂O₃, BiF₃, P₂O₅, CuO, NiO, Cr₂O₃, Fe₂O₃, CoO, Co₂O₃, and CeO₂. In one such embodiment, in addition to the PbO and TeO₂, the starting mixture used to make the Pb—Te—O includes 0.1 to 5 wt % Li₂O and 0.1 to 5 wt % TiO₂, based on the total weight of the starting mixture of the Pb—Te—O, This Pb—Te—O can be designated as Pb—Te—Li—Ti—O. In another embodiment, the Pb—Te—O includes boron, i.e., the Pb—Te—O is Pb—Te—B—O. The starting mixture used to make the Pb—Te—B—O may include (based on the weight of the total starting mixture) PbO that may be 25 to 75 wt %, 30 to 60 wt %, or 30 to 50 wt %; TeO₂ that may be 10 to 70 wt %, 25 to 60 wt %, or 40 to 60 wt %; B₂O₃ that may be 0.1 to 15 wt %, 0.25 to 5 wt %, or 0.4 to 2 wt %. In still further embodiments, in addition to the above PbO, TeO₂, and B₂O₃, the starting mixture used to make the Pb—Te—B—O may include one or more of PbF₂, SiO₂, BiF₃, SnO₂, Li₂O, ZnO, V₂O₅, Na₂O, TiO₂, Al₂O₃, CuO, ZrO₂, CeO₂, or Ag₂O. In such embodiments, one or more of these components may be 0.1-20 wt %, 0.1-15 wt %, or 0.1-10 wt % of the Pb—Te—B—O composition.

### Organic Medium

The organic medium of the instant paste is comprised of solvent and cellulose ester resin. The inorganic components, i.e., the one or more electrically conductive powders and the one or more glass frits, are dispersed in the organic medium by mechanical mixing to form viscous paste having suitable consistency and rheology for printing.

In one embodiment, the organic medium includes cellulose ester resin selected from the group consisting of cellulose acetate butyrate, cellulose acetate propionate, and mixtures thereof. In one embodiment, the cellulose ester resin is cellulose acetate butyrate, e.g., Eastman™ Cellulose Acetate Butyrate CAB-551-0.2 available from Eastman Chemical Co., Kingsport, Tenn., Eastman™ Cellulose Acetate Butyrate CAB-382-20 available from Eastman Chemical Co., Kingsport, Tenn., and mixtures thereof. In a further embodiment, the cellulose ester resin is cellulose acetate propionate, e.g., Eastman™ Cellulose Acetate Propionate CAP-482-20 available from Eastman Chemical Co., Kingsport, Tenn., Eastman™ Cellulose Acetate Propionate CAP-482-0.5 available from Eastman Chemical Co., Kingsport, Tenn., and mixtures thereof. In a still further embodiment, the cellulose ester resin is a mixture of cellulose acetate butyrate and cellulose acetate propionate.

In a non-limiting embodiment, the cellulose ester resin is from 0.025 to 1.5 wt % of the thick film conductive paste, wherein the wt % is based on the total weight of the paste. In a further embodiment, the cellulose ester resin is from 0.05 to 0.75 wt % of the thick film conductive paste, wherein the wt % is based on the total weight of the paste. In a still further embodiment, the cellulose ester resin is from 0.1 to 0.3 wt % of the thick film conductive paste, wherein the wt % is based on the total weight of the paste.

Solvents include those that will dissolve the cellulose ester resin and exhibit screen printing characteristics. In an embodiment, the thick film conductive paste contains one or more solvents selected from the group consisting of diethylene glycol n-butyl ether acetate, diethylene glycol monobutyl ether, 2,2,4-trimethyl-1,3-pentadiol monoisobutyrate and mixtures thereof. The diethylene glycol n-butyl ether acetate is available as Butyl CARBITOL™ Acetate Solvent (The Dow Chemical Company, Midland, Mich.). The diethylene glycol monobutyl ether is available as Butyl CARBITOL™ (The Dow Chemical Company, Midland, Mich.). The 2,2,4-trimethyl-1,3-pentadiol monoisobutyrate is available as Eastman Texanol™ Ester Alcohol (Eastman Chemical Co., Kingsport, Tenn.). The diethylene glycol n-butyl ether acetate solvent appears to be particularly effective in contributing to the formation of narrow fired electrode lines.

In an embodiment, the thick film conductive paste contains a thixotropic rheology modifier dispersed in the organic medium. In one embodiment an amide thixotrope rheology modifier is dispersed in the organic medium. An example of such an amide thixotrope rheology modifier is Thixatrol® MAX, available from Elementis Specialties, Inc., Hightstown, N.J.

In a further embodiment, the organic medium includes one or more additional components selected from the group consisting of pentaerythritol ester of hydrogenated rosin (Foralyn™ 110 ester of Hydogenated Rosin available from Eastman Chemical Co., Kingsport, Tenn.), and surfactants (e.g., Duomee® TDO available from Akzo Nobel Surface Chemistry, LLC, Chicago, Ill.).

The ratio of organic medium in the thick film conductive paste to the inorganic components is dependent on the method of applying the paste and the kind of organic medium used, and it can vary. Usually, the thick film conductive paste will contain 70-95 wt % of inorganic components and 5-30 wt % of organic medium in order to obtain good wetting, wherein the wt % is based on the total weight of the paste, In a further embodiment, the thick film conductive paste will contain 80-95 wt % of inorganic components and 5-20 wt % of organic medium, wherein the wt % is based on the total weight of the paste. In a still further embodiment, the thick film conductive paste will contain 87-93 wt % of inorganic components and 7-213 wt % of organic medium, wherein the wt % is based on the total weight of the paste.

### Preparation of the Thick Film Conductive Paste

In one embodiment, the thick film conductive paste is prepared by mixing the electrically conductive metal, the glass frit, and the organic medium in any order. In some embodiments, the inorganic materials are mixed first, and they are then added to the organic medium. In other embodiments, the electrically conductive metal, which is the major portion of the inorganic components, is slowly added to the organic medium. The viscosity can be adjusted, if needed, by the addition of solvents. Mixing methods that provide high shear are useful.

### Formation of Electrodes

The thick film conductive paste can be deposited, for example, by screen-printing, plating, extrusion, ink-jet printing, shaped or multiple printing.

In this electrode-forming process, the thick film conductive paste is first dried and then heated to remove the organic medium and sinter the inorganic materials. The heating can be carried out in air or an oxygen-containing atmosphere. This step is commonly referred to as “firing.” The firing temperature profile is typically set so as to enable the burnout of organic binder materials from the dried paste composition, as well as any other organic materials present. In one embodiment, the firing temperature is 700 to 950° C. The firing can be conducted in a belt furnace using high transport rates, for example, 100-500 cm/min, with resulting hold-up times of 0.03 to 5 minutes. Multiple temperature zones, for example 3 to 11 zones, can be used to control the desired thermal profile.

In one embodiment, a semiconductor device is manufactured from an article comprising a junction-bearing semiconductor substrate and a silicon nitride insulating film formed on a main surface thereof. The instant thick film conductive paste is applied (e.g., coated or screen-printed) onto the insulating film, in a predetermined shape and thickness and at a predetermined position. The instant thick film conductive paste has the ability to penetrate the insulating layer. Firing is then carried out and the composition reacts with the insulating film and penetrates the insulating film, thereby effecting electrical contact with the silicon substrate and as a result the electrode is formed.

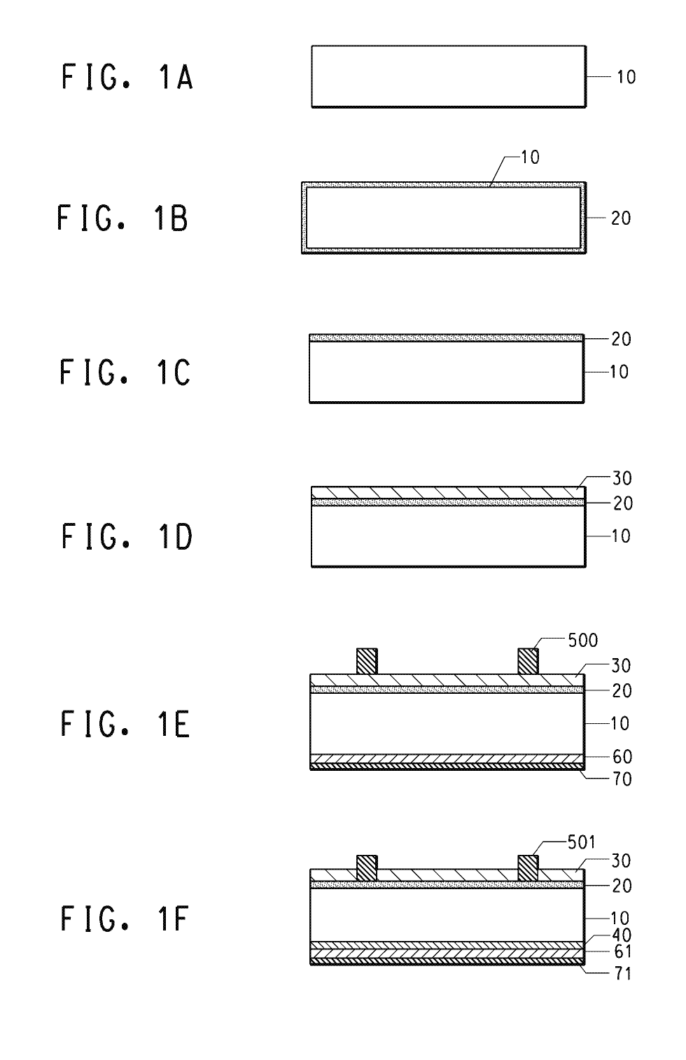

An example of this method of forming the electrode is described below in conjunction with FIGS. 1A-1F.

FIG. 1A shows a single crystal or multi-crystalline p-type silicon substrate 10.

In FIG. 1B, an n-type diffusion layer 20 of the reverse conductivity type is formed by the thermal diffusion of phosphorus using phosphorus oxychloride as the phosphorus source. In the absence of any particular modifications, the diffusion layer 20 is formed over the entire surface of the silicon p-type substrate 10. The depth of the diffusion layer can be varied by controlling the diffusion temperature and time, and is generally formed in a thickness range of about 0.3 to 0.5 microns. The n-type diffusion layer may have a sheet resistivity of several tens of ohms per square up to about 120 ohms per square.

After protecting the front surface of this diffusion layer with a resist or the like, as shown in FIG. 1C the diffusion layer 20 is removed from the rest of the surfaces by etching so that it remains only on the front surface. The resist is then removed using an organic solvent or the like.

Then, as shown in FIG. 1D an insulating layer 30 which also functions as an anti-reflection coating (ARC) is formed on the n-type diffusion layer 20. The insulating layer is commonly silicon nitride, but can also be a SiNₓ:H film (i.e., the insulating film comprises hydrogen for passivation during subsequent firing processing), a titanium oxide film, a silicon oxide film, or a silicon oxide/titanium oxide film. A thickness of about 700 to 900 Å of a silicon nitride film is suitable for a refractive index of about 1.9 to 2.0. Deposition of the insulating layer 30 can be by sputtering, chemical vapor deposition, or other methods,

Next, electrodes are formed. As shown in FIG. 1E, the thick film conductive paste of the present invention 500 is screen-printed to create the front electrode on the insulating film 30 and then dried. In addition, a back side silver or silver/aluminum paste 70, and an aluminum paste 60 are then screen-printed onto the back side of the substrate and successively dried. Firing is carried out in an infrared belt furnace at a temperature range of approximately 750 to 950° C. for a period of from several seconds to several tens of minutes.

Consequently, as shown in FIG. 1 F, during firing, aluminum diffuses from the aluminum paste 60 into the silicon substrate 10 on the back side thereby forming a p+ layer 40 containing a high concentration of aluminum dopant. This layer is generally called the back surface field (BSF) layer, and helps to improve the energy conversion efficiency of the solar cell.

Firing converts the dried aluminum paste 60 to an aluminum back electrode 61. The back side silver or silver/aluminum paste 70 is fired at the same time, becoming a silver or silver/aluminum back electrode, 71. During firing, the boundary between the back side aluminum and the back side silver or silver/aluminum assumes the state of an alloy, thereby achieving electrical connection. Most areas of the back electrode are occupied by the aluminum electrode 61, owing in part to the need to form a p+ layer 40. Because soldering to an aluminum electrode is impossible, the silver or silver/aluminum back electrode 71 is formed over portions of the back side as an electrode for interconnecting solar cells by means of copper ribbon or the like. In addition, the front side thick film conductive paste 500 of the present invention sinters and penetrates through the insulating film 30 during firing, and thereby achieves electrical contact with the n-type layer 20. This type of process is generally called “fire through.” The fired electrode 501 of FIG. 1F clearly shows the result of the fire through.

### EXAMPLES

### Preparation of Polymer Solutions

A 500 ml three-neck round bottom flask was fitted with an overhead stirrer, nitrogen purge, thermocouple, and heating mantle. The type of solvent in the amount listed in Table I was added to the flask and heated to 60° C. The indicated amount of polymeric resin was then added slowly to the flask with stirring. The mixture was allowed to stir for 2.5 hr at 60° C. under nitrogen purge, during which time the resin dissolved to yield a viscous solution. Polymer solutions prepared with Foralyn™ 110 Ester of Hydrogenated Rosin were allowed to stir for 6 hours.

### Resins Used:

Eastman™ Cellulose Acetate Butyrate CAB-551-0.2 (Eastman Chemical Co., Kingsport, Tenn.)

Eastman™ Cellulose Acetate Propionate CAP-482-20 (Eastman Chemical Co., Kingsport, Tenn.)

Eastman™ Cellulose Acetate Butyrate CAB-382-20 (Eastman Chemical Co., Kingsport, Tenn.)

Eastman™ Cellulose Acetate Propionate CAP-482-0.5 (Eastman Chemical Co., Kingsport, Tenn.)

Foralyn™ 110 Ester of Hydrogenated Rosin (Eastman Chemical Co., Kingsport, Tenn.)—pentaerythritol ester of hydrogenated rosin

ETHOCEL™ Std200 Ethylcellulose (The Dow Chemical Company, Midland, Mich.)

Aqualon™ N22 ethylcellulose (Ashland, Covington, Ky.)

Aqualon™ T200 ethylcellulose (Ashland, Covington, Ky.)

### Solvents Used:

Butyl CARBITOL™ Acetate Solvent (The Dow Chemical Company, Midland, Mich.)—diethylene glycol n-butyl ether acetate

Butyl CARBITOL™ (The Dow Chemical Company, Midland, Mich.)—diethylene glycol monobutyl ether

Eastman Texanol™ Ester Alcohol (Eastman Chemical Co., Kingsport, Tenn.)—2,2,4-trimethyl-1,3-pentadiol monoisobutyrate

TABLE I

| | Resin | | Solvent | |
|---|---|---|---|---|
| | | Amount | | Amount |
| Solution | Description | (g) | Description | (g) |
| 1 | CAB-551-0.2 | 60 | Butyl CARBITOL ™ | 240 |
| | | | Acetate | |
| 2 | CAP-482-20 | 30 | Butyl CARBITOL ™ | 270 |
| | | | Acetate | |
| 3 | CAB-382-20 | 30 | Butyl CARBITOL ™ | 270 |
| | | | Acetate | |
| 4 | CAP-482-0.5 | 60 | Butyl CARBITOL ™ | 240 |
| | | | Acetate | |
| 5 | Foralyn ™ 110 | 150 | Butyl CARBITOL ™ | 150 |
| | | | Acetate | |
| 6 | Foralyn ™ 110 | 150 | Butyl CARBITOL ™ | 150 |
| 7 | Foralyn ™ 110 | 150 | Eastman Texanol ™ | 150 |
| 8 | ETHOCEL ™ | 30 | Butyl CARBITOL ™ | 270 |
| | Std200 | | Acetate | |
| 9 | Aqualon ™ N22 | 30 | Butyl CARBITOL ™ | 270 |
| | | | Acetate | |
| 10 | Aqualon ™ T200 | 30 | Eastman Texanol ™ | 270 |
| 11 | Aqualon ™ N22 | 30 | Eastman Texanol ™ | 270 |

### Paste Preparation

A number of pastes of the instant invention comprising different mixtures of resins and solvents were prepared. The relative amounts of the various constituents used are shown in Tables II and III for Examples 1-6 and 7-12 respectively. Pastes were also prepared using constituents known in the art to provide good electrical properties in silicon solar cells employing a silicon nitride based anti-reflection coating and the amounts of the various constituents used are shown in Tables IV for the Comparative Experiments A-D which are based on ethyl cellulose resin.

Constituents used in these preparations in addition to the above solutions were:

Duomeen® TDO (Akzo Nobel Surface Chemistry, LLC, Chicago Ill.)—surfactant

Thixatrol® MAX (Elementis Specialties, Inc., Hightstown, N.J.)—amide rheology modifier

Thixatrol® ST (Elementis Specialties, Inc., Hightstown, N.J.)−rheology modifier

Frit Additive—Li₂RuO₃

Glass frit—44.51 wt % PbO, 47.74 wt % TeO₂, 0.48 wt % B₂O₃, 6.83 \wt % B₂O₃ and 0.44 wt % Li₂O

Silver Powder 1—spherically shaped particles, a tap density of 5 to 6, a surface area of 0.3 to 0.6 m²/gm Ag and a particle size distribution of d₁₀ of 1.0 to 1.5 μm, d₅₀ of 1.5 to 2.3 μm and d₉₀ of 2.5 to 3.5 μm.

Silver Powder 2—irregularly shaped particles, a tap density of 0.8 to 1.2, a surface area of 4.0 to 6.0 m²/gm Ag and a particle size distribution of d₁₀ of 1.0 to 3.0 μm, d₅₀ of 6.0 to 11.0 μm and d₉₀ of 18.0 to 25.0 μm.

Eastman Texanol™ Ester Alcohol (Eastman Chemical Co., Kingsport, Tenn.)—2,2,4-trimethyl-1,3-pentadiol monoisobutyrate

Butyl CARBITOL™ Acetate Solvent (The Dow Chemical Company, Midland, Mich.)—diethylene glycol n-butyl ether acetate

Butyl CARBITOL™ (The Dow Chemical Company, Midland, Mich.)—diethylene glycol monobutyl ether

Formulation to the desired viscosity with Eastman Texanol™ Ester Alcohol (Eastman Chemical Co., Kingsport, Tenn.)—2,2,4-trimethyl-1,3-pentadiol monoisobutyrate as needed.

Pastes were prepared in the following manner. The relative amounts of solvent, resin and surfactant indicated in Tables II and III for Examples 1-6 (Ex 1-6) and Examples 7-12 (Ex 7-12) respectively and Table IV for Comparative Experiments A-D (CE A-D) was weighed then mixed in a mixing can for 15 minutes. Glass frit and silver powder in indicated amounts were added and mixed for another 15 minutes. Since Ag is the major part of the solids of the instant paste, it was added incrementally to ensure better wetting. When well mixed, the paste was repeatedly passed through a 3-roll mill for at progressively increasing pressures from 0 to 400 psi. The gap of the rolls was adjusted to 1 mil. The degree of dispersion was measured by fineness of grind (FOG). The FOG value was equal to or less than 20/10. If more than one silver was used in the recipe, the silver with the smaller d₅₀ was incorporated first. This sample was then roll milled before the silver powder(s) with larger d₅₀'s were incorporated. After the final silver addition, the paste with the mixed silver system was milled again according to the above specifications. Also indicated in Tables II-IV are the viscosities of the pastes.

TABLE II
Paste Compositions, Examples 1-6

| | Ex 1 | Ex 2 | Ex 3 | Ex 4 | Ex5 | Ex 6 |
|---|---|---|---|---|---|---|
| Constituents | | | | | | |
| Solution 2 | | 0.75 | | 0.75 | | 0.75 |
| Solution 3 | 0.75 | | 0.75 | | 0.75 | |
| Solution 1 | 0.37 | 0.37 | 0.37 | 0.37 | 0.37 | 0.37 |
| Solution 5 | 2.63 | 2.63 | 2.63 | 2.63 | 2.63 | 2.63 |
| Duomeen ® TDO | 0.51 | 0.51 | 0.51 | 0.51 | 0.51 | 0.51 |
| Thixatrol ® ST | 0.51 | 0.51 | 0.51 | 0.51 | | |
| Thixatrol ® MAX | | | | | 0.51 | 0.51 |
| Frit Additive | 0.05 | 0.05 | 0.05 | 0.05 | 0.05 | 0.05 |
| Glass frit | 1.62 | 1.62 | 1.62 | 1.62 | 1.62 | 1.62 |
| Silver Powder 1 | 89.66 | 89.66 | 85.10 | 85.10 | 89.66 | 89.66 |
| Silver Powder 2 | | | 4.56 | 4.56 | | |
| Eastman Texanol ™ | 1.01 | 1.01 | 1.01 | 1.01 | 1.01 | 1.01 |
| Butyl CARBITOL ™ Acetate | 1.62 | 1.62 | 1.62 | 1.62 | 1.62 | 1.62 |
| Butyl CARBITOL ™ | 0.71 | 0.71 | 0.71 | 0.71 | 0.71 | 0.71 |
| Formulation with Eastman | 0.58 | 0.56 | 0.79 | 0.79 | 0.61 | 0.56 |
| Texanol ™ | | | | | | |
| Total (wt %) | 100 | 100 | 100 | 100 | 100 | 100 |
| Solids (wt %) | 90.29 | 90.3 | 90.16 | 90.03 | 90.25 | 90.28 |
| Brookfield Viscosity (Pa · s) | | | | | | |
| 0.5 rpm/3 min | 870 | 730 | 940 | 840 | 1070 | 880 |
| 10 rpm/36 sec | 303 | 284 | 336 | 310 | 334 | 294 |
| 10 rpm/3 min | 260 | 255 | 275 | 280 | 285 | 266 |
| 50 rpm/3 min | 54 | 52 | 68 | 68 | 75 | 47 |

TABLE III
Paste Compositions, Examples 7-12

| | Ex 7 | Ex 8 | Ex 9 | Ex 10 | Ex 11 | Ex 12 |
|---|---|---|---|---|---|---|
| Constituents | | | | | | |
| Solution 2 | 0.75 | 0.74 | 0.74 | 0.74 | 0.74 | 1.48 |
| Solution 1 | 0.37 | | | | | 0.74 |
| Solution 4 | | 0.37 | 0.37 | 0.37 | 0.37 | |
| Solution 6 | | | | | 2.62 | |
| Solution 5 | 2.62 | 2.62 | 2.62 | 2.61 | | 2.60 |
| Duomeen ® TDO | 0.50 | 0.50 | 0.50 | 0.50 | 0.50 | 0.50 |
| Thixatrol ® ST | | | 0.50 | | | |
| Thixatrol ® MAX | 0.50 | 0.50 | | 0.50 | 0.50 | 0.50 |
| Frit Additive | 0.07 | 0.07 | 0.07 | 0.07 | 0.07 | 0.07 |
| Glass frit | 1.62 | 1.61 | 1.61 | 1.61 | 1.61 | 1.60 |
| Silver Powder 1 | 86.09 | 89.34 | 89.34 | 85.77 | 89.34 | 88.68 |
| Silver Powder 2 | 3.58 | | | 3.57 | | |
| Eastman Texanol ™ | 1.01 | 1.01 | 1.01 | 1.01 | 1.01 | 1.00 |
| Butyl CARBITOL ™ Acetate | 1.62 | 1.61 | 1.61 | 1.61 | 1.61 | 1.60 |
| Butyl CARBITOL ™ | 0.71 | 0.70 | 0.70 | 0.70 | 0.70 | 0.70 |
| Formulation with Eastman | 0.81 | 0.55 | 0.55 | 0.85 | 0.63 | 0.55 |
| Texanol ™ | | | | | | |
| Total (wt %) | 100 | 100 | 100 | 100 | 100 | 100 |
| Solids (wt %) | 90.12 | 90.43 | 90.56 | 90.23 | 90.26 | 89.93 |
| Brookfield Viscosity (Pa · s) | | | | | | |
| 0.5 rpm/3 min | 800 | 680 | 680 | 960 | 980 | 1050 |
| 10 rpm/36 sec | 287 | 287 | 287 | 290 | 275 | 275 |
| 10 rpm/3 min | 256 | 258 | 258 | 260 | 250 | 256 |
| 50 rpm/3 min | 64 | 60 | 62 | 61 | 56 | 61 |

TABLE IV
Paste Compositions, Comparative Experiments A-D

| | CE A | CE B | CE C | CE D |
|---|---|---|---|---|
| Constituents | | | | |
| Solution 10 | 0.74 | | | |
| Solution 11 | 0.74 | | | |
| Solution 8 | | 0.74 | 0.74 | 0.74 |
| Solution 9 | | 0.74 | 0.74 | 0.74 |
| Solution 7 | 2.62 | | | |
| Solution 6 | | | | 2.61 |
| Solution 5 | | 2.61 | 2.62 | |
| Duomeen ® TDO | 0.50 | 0.50 | 0.50 | 0.50 |
| Thixatrol ® ST | 0.50 | | | 0.50 |
| Thixatrol ® MAX | | 0.50 | 0.50 | |
| Frit Additive | 0.07 | 0.07 | 0.07 | 0.07 |
| Glass frit | 1.61 | 1.61 | 1.61 | 1.61 |
| Silver Powder 1 | 89.34 | 85.77 | 89.34 | 85.77 |
| Silver Powder 2 | | 3.57 | | 3.57 |
| Eastman Texanol ™ | 1.01 | 1.01 | 1.01 | 1.01 |
| Butyl CARBITOL ™ Acetate | 1.62 | 1.61 | 1.61 | 1.61 |
| Butyl CARBITOL ™ | 0.70 | 0.70 | 0.70 | 0.70 |
| Formulation with | 1.06 | 0.58 | 0.55 | 1.01 |
| Eastman Texanol ™ | | | | |
| Total (wt %) | 100 | 100 | 100 | 100 |
| Solids (wt %) | 89.5 | 90.06 | 90.12 | 89.6 |
| Brookfield Viscosity (Pa · s) | | | | |
| 0.5 rpm/3 min | 810 | 760 | 730 | 680 |
| 10 rpm/36 sec | 291 | 271 | 289 | 303 |
| 10 rpm/3 min | 274 | 258 | 266 | 266 |
| 50 rpm/3 min | 60 | 59 | 54 | 54 |

Samples of the pastes of the Examples and the Comparative Experiments were screen printed onto six inch square multicrystalline silicon wafers (Gintech Energy Corp., Taiwan) to determine line spreading. An 80 micron wide line cell pattern designed to be compatible with 65 ohm/square emitters was used. After line measurements were made the paste was subjected to an IR drying process to determine line spreading that occurred as the sample. To simulate the IR drying process a 12-zone furnace (Despatch Industries, Minneapolis, Minn.) was programmed with the following zone settings: zone 1; 330° C., zone 2: 415° C., zone 3: 415° C., zone 4: 385° C., zones 5-8: 250° C., zones 9-12: 260° C. and a belt speed of 220 inches/min. Samples were then fired in a multi-zone furnace (Despatch Industries, Minneapolis, Minn.) with the following zone settings: zone 1: 500° C., zone 2: 550° C., zone 3: 610° C., zone 4: 700° C., zone 5: 800° C., zone 9: ranged from 885° C. to 960° C.

Line dimensions were determined with a Optelics H1200 Confocal Microscope (Lasertec, San Jose, Calif.). A step and repeat program was used to obtain 30 average measurements of printed finger dimensions across the area of the 6″ square wafers. An overall average was calculated from the 30 individual measurements to obtain an average line dimension for that particular paste. Line dimensions were obtained on as-printed wafers, after the IR drying step, and after the firing step.

Line spreading data is summarized in Table V.

TABLE V
Line Width Summary

Line Width (μm)

| | Ex | Ex | Ex | Ex | Ex | Ex |
|---|---|---|---|---|---|---|
| | 1 | 2 | 3 | 4 | 5 | 6 |
| As-printed | 86.4 | 87.2 | 79.1 | 88.4 | 82.7 | 86.7 |
| IR Dry | 96.4 | 97.2 | 90.4 | 94.9 | 94.4 | 95.3 |
| Fired | 98.4 | 98.6 | 91.3 | 95.4 | 96.6 | 96.5 |
| | Line Width (μm) | | | | | |
| | Ex | Ex | Ex | Ex | Ex | Ex |
| | 7 | 8 | 9 | 10 | 11 | 12 |
| As-printed | 78.4 | 82.3 | 88.4 | 88.8 | 88.5 | 83 |
| IR Dry | 95.3 | 96.1 | 99.3 | 95.7 | 98.6 | 97.3 |
| Fired | 96.8 | 95.2 | 98.9 | 96.1 | 98 | 95.6 |

| | Line Width (μm) | | | |
|---|---|---|---|---|
| | CE | CE | CE | CE |
| | A | B | C | D |
| As-printed | 88.8 | 86.7 | 78.2 | 79.9 |
| IR Dry | 113.9 | 112.1 | 113.5 | 110.8 |
| Fired | 124.6 | 113.2 | 111.9 | 109.6 |

The line spreading data indicate that the pastes of the Examples, i.e., the paste of the invention containing cellulose ester resins, exhibited less line spreading compared with the pastes of the Comparative Experiments, i.e., the ethyl cellulose-based pastes. The reduced line spreading is evident after the IR drying step and the final firing step. It is evident to one skilled in the art that narrow fingers translate to less shadowing of the surface of the solar cell wafer which, in turn, leads to improved solar cell performance.

What is claimed is:

1. A thick film conductive paste comprising:
a) one or more electrically conductive powders:
b) one or more glass frits: and
c) an organic medium comprising solvent and cellulose ester resin, wherein said one or more electrically conductive powders and said one or more glass frits are dispersed in said organic medium.

2. The thick film conductive paste of claim 1, wherein said cellulose ester resin is selected from the group consisting of cellulose acetate propionate, cellulose acetate butyrate, and mixtures thereof.

3. The thick film conductive paste of claim 1, wherein said solvent is selected from the group consisting of diethylene glycol n-butyl ether acetate, diethylene glycol monobutyl ether, 2,2,4-trimethyl-1,3-pentadiol monoisobutyrate and mixtures thereof.

4. The thick film conductive paste of claim 3, wherein said solvent is diethylene glycol n-butyl ether acetate.

5. The thick film conductive paste of claim 1, wherein said one or more electrically conductive powders are silver powders.

6. The thick film conductive paste of claim 5, said silver powders comprising a silver powder with spherically shaped particles, a tap density of 5 to 6, a surface area of 0.3 to 0.6 m²/gm Ag and a particle size distribution of d₁₀ of 1.0 to 1.5 μm, d₅₀ of 1.5 to 2.3 μm and d₉₀ of 2.5 to 3.5 μm.

7. The thick film conductive paste of claim 6, said silver powders further comprising a silver powder with irregularly shaped particles, a tap density of 0.8 to 1.2, a surface area of 4.0 to 6.0 m²/gm Ag and a particle size distribution of d₁₀ of 1.0 to 3.0 μm, d₅₀ of 6.0 to 11.0 μm and d₉₀ of 18.0 to 25.0 μm.

8. The thick film conductive paste of claim 1, further comprising an amide thixotrope dispersed in said organic medium.

9. The thick film conductive paste of claim 1, said one or more conductive powders comprising a silver powder with spherically shaped particles, a tap density of 5 to 6, a surface area of 0.3 to 0.6 m²/gm Ag and a particle size distribution of d₁₀ of 1.0 to 1.5 μm, d₅₀ of 1.5 to 2.3 μm and d₉₀ of 2.5 to 3.5 μm, said solvent is selected from the group consisting of diethylene glycol n-butyl ether acetate, diethylene glycol monobutyl ether, 2,2,4-trimethyl-1,3-pentadiol monoisobutyrate and mixtures thereof, and said cellulose ester resin is selected from the group consisting of cellulose acetate propionate, cellulose acetate butyrate, and mixtures thereof.

10. The thick film conductive paste of claim 9, wherein said solvent is diethylene glycol n-butyl ether acetate.

11. The thick film conductive paste of claim 9, further comprising an amide thixotrope dispersed in said organic medium.

12. The thick film conductive paste of claim 9, wherein said glass frit is Pb—Te—O.

13. A semiconductor device comprising an electrode formed from a thick film conductive paste comprising:
a) one or more electrically conductive powders;
b) one or more glass frits; and
c) an organic medium comprising solvent and cellulose ester resin, wherein said one or more electrically conductive powders and said one or more glass frits are dispersed in said organic medium,
wherein said thick film conductive paste has been fired to remove the organic medium and form said electrode.

14. The semiconductor device of claim 13, said one or more conductive powders comprising a silver powder with spherically shaped particles, a tap density of 5 to 6, a surface area of 0.3 to 0.6 m²/gm Ag and a particle size distribution of d₁₀ of 1.0 to 1.5 μm, d₅₀ of 1.5 to 2.3 μm and d₉₀ of 2.5 to 3.5 μm, said solvent is selected from the group consisting of diethylene glycol n-butyl ether acetate, diethylene glycol monobutyl ether, 2,2,4-trimethyl-1,3-pentadiol monoisobutyrate and mixtures thereof, and said cellulose ester resin is selected from the group consisting of cellulose acetate propionate, cellulose acetate butyrate, and mixtures thereof.

15. The semiconductor device of claim 13 in the form of a solar cell.

16. The semiconductor device of claim 14 in the form of a solar cell.

17. The semiconductor device of claim 13 in the form of a solar cell, wherein said solar cell has a front side, that is, sun side, and a back side and wherein said electrode is an electrode on said front side of said solar cell.

18. The semiconductor device of claim 14 in the form of a solar cell, wherein said solar cell has a front side, that is, sun side, and a back side and wherein said electrode is an electrode on said front side of said solar cell.
